(19) United States
(12) Patent Application Publication
(10) Pub. No.: US 2026/0324336 A1
(43) Pub. Date: Oct. 15, 2026

(54) PLASMA DOPING AND DEPOSITION PROCESSES FOR INTEGRATED METAL CONTACT FORMATION

(71) Applicant: Applied Materials, Inc., Santa Clara, CA (US)

(72) Inventors: Taegon Kim, Seoul (KR); Michael Noel Kennedy, Boston, MA (US); Joseph C. Olson, Beverly, MA (US); Sage Toko Garrett Doshay, Saratoga, CA (US)

(73) Assignee: Applied Materials, Inc., Santa Clara, CA (US)

(21) Appl. No.: 19/176,378

(22) Filed: Apr. 11, 2025

(51) Int. Cl. H10P 70/00; H10P 14/43; H10P 72/00

(52) U.S. Cl. CPC H10P 70/27; H10P 14/43; H10P 72/0454

(57) ABSTRACT

Disclosed herein are approaches for integrated processes for forming logic and memory devices using monolayer doping with integrated metal contact deposition for low-temperature reduction of contact resistance. Methods may include performing a plasma treatment on a semiconductor substrate to remove a residue layer along an exposed surface of the semiconductor substrate, forming a dopant-containing layer over the exposed surface, and forming a contact by forming one or more metal layers over the exposed surface.

### FIELD OF THE DISCLOSURE

The present embodiments relate to approaches for device formation and, more particularly, to approaches including monolayer doping with integrated metal contact deposition for contact resistance reduction via low-temperature processing.

### BACKGROUND OF THE DISCLOSURE

As semiconductor devices such as logic and memory devices continue to scale to smaller dimensions, the use of conventional processing and materials to fabricate such devices is increasingly challenging. For example, excessive thermal budget is detrimental for devices including copper interconnects, as process temperatures greater than approximately 500⁰C degrade copper integrity and compromise the device characteristics. In addition, it is advantageous to decrease gate contact resistivity for improved device power efficiency and performance, especially as device sizes scale down, which increases contact resistance in proportion to the gate area scaling.

Accordingly, improved integration approaches are needed for reducing device contact resistance, improving efficiency, and decreasing power consumption.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include performing a plasma treatment on a semiconductor substrate to remove a residue layer along an exposed surface of the semiconductor substrate, and forming a dopant-containing layer over the exposed surface. The method may further include forming a contact by forming one or more metal layers over the dopant-containing layer.

In another aspect, a method of forming a contact may include performing a plasma treatment on a semiconductor substrate to remove a residue layer along an upper surface within a trench, and forming a dopant-containing layer over the upper surface. The method may further include forming a contact over the upper surface within the trench by forming one or more metal layers over a dopant-containing monolayer, wherein the dopant-containing monolayer is formed by performing a radical cleaning process to the dopant-containing layer.

In yet another aspect, a semiconductor cluster tool may include a first processing tool in a first chamber, wherein the first processing tool is operable to perform a plasma treatment on a semiconductor substrate to remove a residue layer along an exposed surface of the semiconductor substrate. The semiconductor cluster tool may further include a second processing tool in a second chamber, wherein the second processing tool is operable to form a dopant-containing layer over the exposed surface by performing a second treatment to the exposed surface. The semiconductor cluster tool may further include a third processing tool operable to form a metal contact by forming one or more metal layers over a dopant-containing monolayer, wherein the dopant-containing monolayer is formed by performing a radical cleaning process to the dopant-containing layer. The first chamber and the second chamber may be operably connected to a same load-lock system, wherein the semiconductor substrate is maintained under a continuous vacuum throughout the first plasma treatment and the second treatment.

### BRIEF DESCRIPTION OF THE DRAWINGS

The accompanying drawings illustrate exemplary approaches of the disclosure, including the practical application of the principles thereof, as follows:

FIG. 1 illustrates a residue layer removal process according to embodiments of the present disclosure;

FIG. 2 illustrates a dopant-containing layer formation process according to embodiments of the present disclosure;

FIG. 3 illustrates a residue removal process according to embodiments of the present disclosure;

FIG. 4 illustrates a contact formation process according to embodiments of the present disclosure;

FIG. 5 illustrates a metal fill process according to embodiments of the present disclosure;

FIG. 6 is a schematic diagram of a cluster tool according to embodiments of the disclosure;

FIG. 7 is a schematic diagram of a system for directing radicals into a semiconductor structure, in accordance with embodiments of the present disclosure; and

FIG. 8 illustrates a schematic diagram of a plasma doping system according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of "slices", or "near-sighted" cross-sectional views, omitting certain background lines otherwise visible in a "true" cross-sectional view, for illustrative clarity. Furthermore, for clarity, some reference numbers may be omitted in certain drawings.

### DETAILED DESCRIPTION

Methods, devices, and systems in accordance with the present disclosure will now be described more fully hereinafter with reference to the accompanying drawings, where various embodiments are shown. The methods, devices, and systems may be embodied in many different forms and are not to be construed as being limited to the embodiments set forth herein. Instead, these embodiments are provided so the disclosure will be thorough and complete, and will fully convey the scope of the methods to those skilled in the art.

Increased contact resistance during device formation is a result of scaling down to smaller device sizes, as resistance is inversely proportional to contact size. Embodiments described herein enable contact resistance to be reduced by decreasing the contact resistivity, using a low-temperature process that can be integrated with advanced integration flows involving, e.g., copper interconnects. As the devices scale down, the contact resistance may stay constant or potentially even decrease, depending on the ratio of the improved resistivity to the ratio of the scaling factor.

More specifically, approaches described herein enable lowered contact resistance through an integrated process flow combination of low-temperature plasma processing, monolayer doping (MLD), and metal contact deposition. Near-surface incorporation of dopant atoms, which occurs during a metal silicide formation, leads to a reduced contact resistance. Due to the relatively low thermal budget associated with the metal silicide formation, there is minimal diffusion associated with this dopant incorporation. This reduced contact resistance further results in improved device efficiency and decreased device power consumption.

In one example integrated process flow used to form trench contacts, a first plasma process may clean a semiconductor surface, e.g., may remove any native oxide and/or surface defects present along an exposed trench bottom. Next, a dopant-containing layer may be formed over the trench bottom. In some embodiments, the dopant-containing layer may be formed by a second treatment, which may be a multi-layer deposition process such as atomic layer deposition (ALD), chemical vapor deposition (CVD), plasma-enhanced chemical vapor deposition (PECVD), or another wet chemistry or gas-phase-based deposition process, to form a dopant-containing multilayer (e.g., a gallium (Ga)-containing compound) on the cleaned surface along the exposed trench bottom, where the interfacial layer of dopant-containing compound is chemisorbed to the exposed trench bottom. A radical cleaning process may then be performed to remove excess physisorbed layers of dopant-containing material, resulting in the creation of a chemisorbed monolayer of the dopant-containing compound along the trench bottom.

Next, a contact may be formed over the dopant-containing layer by depositing one or more metal layers in the trench bottom while the semiconductor substrate is at a temperature greater than 250°C. In some embodiments, metal layer formation via CVD occurs while the semiconductor device is maintained at a temperature between 300°C – 450°C. This deposition process incorporates the surface dopant into the bulk semiconductor material (e.g., Si) and simultaneously forms a metal silicide/metal contact to the device. These processes are all performed in one integrated process flow without breaking vacuum to produce the desired semiconductor-metal stack with reduced contact resistance. If the vacuum is broken and native oxide re-forms, the deposited dopant-containing compound will not chemically bind with the exposed substrate surface and all layers of the physisorbed organo-dopant material would then “burn off” during the elevated temperature of the metal deposition process, as there would be no chemisorbed layer along the trench bottom.

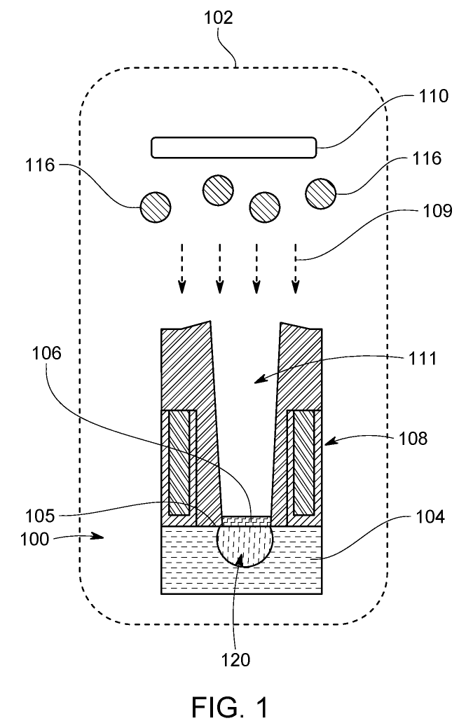

FIG. 1 illustrates a semiconductor substrate 100 provided in a semiconductor processing apparatus 102 or system. While the semiconductor substrate 100 is located within the semiconductor processing apparatus 102, it may be understood that high vacuum conditions are maintained. For example, during ion implantation of the semiconductor substrate 100, vacuum levels of less than 10e-3 torr may be maintained in the end station housing the semiconductor substrate 100. During other processing operations, such as plasma-based operations, the vacuum levels of less than 10e-1 torr may be maintained. While during idle periods, or during transfers between chambers, vacuum levels of less than 10e-4 torr may be maintained according to non-limiting embodiments of the disclosure. Embodiments herein are not limited in this context, however.

At the stage represented in FIG. 1, the semiconductor substrate 100 may be placed into the semiconductor processing apparatus 102 after having received processing through multiple operations in order to fabricate devices such as logic devices, memory devices, or other semiconductor devices. In the non-limiting example shown, the semiconductor substrate 100 may include a substrate base 104, formed of bulk semiconductor material, and a set of gate structures 108 defining a trench 111. A contact area 120 may be formed within the substrate base 104 at the bottom of the trench 111 using, e.g., an ion implantation process (not shown). In some embodiments, the semiconductor substrate 100 may also include a residue, such as a native oxide layer 106, disposed on an exposed/upper surface 105 thereof. The native oxide layer 106 may represent a layer formed after processing to remove any other materials from the surface of the substrate base 104. The formation of native oxide on silicon and like semiconductors in well-known and will not be discussed in detail herein. However, even when monocrystalline silicon is processed to remove any oxide or other non-silicon material from an outer surface, a native oxide may tend to form upon exposure to oxygen-containing (including water vapor) atmosphere, such as the ambient outside of a vacuum processing tool. Moreover, native oxide tends to be self-limiting in thickness, such that the thickness of the native oxide layer 106 may be assumed to be no more than 4 nm – 8 nm in some non-limiting embodiments.

As further shown in FIG. 1, the upper surface 105 of semiconductor substrate 100 may be exposed to a first plasma treatment 109, such as a plasma clean operation. In some embodiments, the first plasma treatment 109 may employ a plasma source 110 located in the semiconductor processing apparatus 102. The plasma source 110 may represent any suitable apparatus to generate a plasma, and in some instances may represent an RF radical source. In any case, the plasma source 110 may generate a cleaning species 116, which species may include ions and neutrals, including radicals, or hydrogen (H) or other atomic species.

In the case of the cleaning species 116 including ions, during the plasma clean operation, the energy of the ions may be maintained below 100 eV, such as in the range of several eV to 30 eV, in some non-limiting embodiments. In some embodiments, the cleaning species 116 may represent known reactive species (e.g., H) that tend to chemically react to etch the native oxide layer 106, even when the energy of such reactive species is on the order of several eV. In various embodiments, the cleaning species 116 may selectively etch the native oxide layer 106 with respect to the substrate base 104. As such, the native oxide layer 106 may be removed from the substrate base 104 with little or no etching or damage to the substrate base 104 due to the low energy and etch selectivity of the cleaning species 116.

According to some embodiments, the plasma clean operation of FIG. 1 may be accomplished by generating hydrogen species in a plasma chamber of plasma source 110, and directing the hydrogen species to the upper surface 105 when the substrate 100 is at a cleaning temperature, such as between room temperature and 100° C. The hydrogen species may be ionized hydrogen with noble gas dilution. In some non-limiting embodiments, the noble gas dilution may be Xenon (Xe) or Argon (Ar) to promote removal of the native oxide layer 106. The Xe or Ar ion bombardment of the upper surface 105 produces excited SiOx states, which then chemically react with the hydrogen radicals and are desorbed from the upper surface 105. The hydrogen radicals extracted from the plasma chamber reach the unbiased, room-temperature wafer at an energy of approximately 1-100eV, while the pressure in the process chamber is carefully moderated, creating a processing regime where the native oxide layer 106 is removed without etching the underlying substrate base 104.

In some embodiments, the plasma clean operation may involve a plurality of sub-operations. For example, a first plasma clean sub-operation may be performed by generating a cleaning species from a plasma source that reacts to remove a portion of or all of the native oxide layer 106. This cleaning species may be a species different from hydrogen, for example. A second plasma clean sub-operation may then involve generating a hydrogen plasma and directing the hydrogen species to the upper surface 105 to remove any residual oxide, carbon, or other contaminant and to terminate the upper surface 105 with a hydrogen passivation. In other examples, only hydrogen species may be used to perform native oxide removal and hydrogen termination. In any case, the plasma clean operation may be completed by generating a hydrogen plasma and directing hydrogen species to the upper surface 105 to form a hydrogen-terminated upper surface 105. Said differently, the plasma clean operation of FIG. 1 may be considered to involve the sub-operations of native oxide removal followed by hydrogen termination of the upper surface 105. Likewise, in some embodiments, the cleaning species 116 may represent more than one species, such as a separate non-hydrogen species to etch the native oxide layer 106, as well as a hydrogen species to hydrogen-terminate the upper surface 105 after native oxide layer 106 removal.

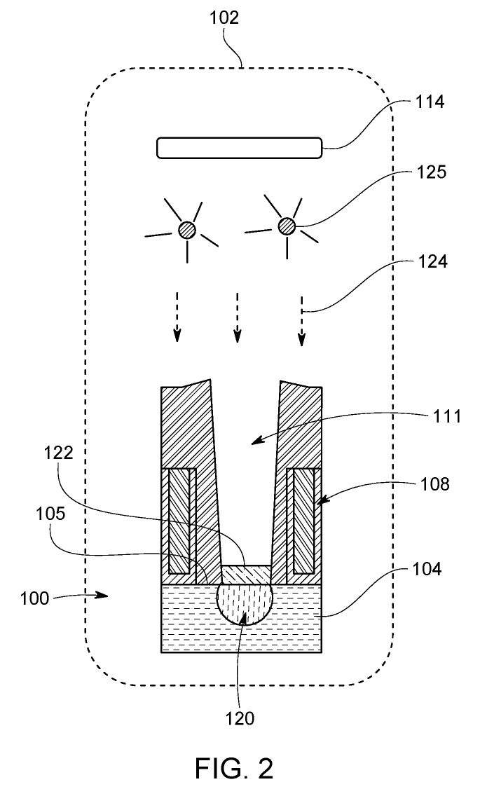

As shown in FIG. 2, a dopant-containing layer 122 may then be formed over the upper surface 105. In some embodiments, the dopant-containing layer 122 may be formed over the contact area 120 in the substrate base 104. The dopant-containing layer 122 may be formed by a second treatment 124 via a second source 114 located in the semiconductor processing apparatus 102. In some embodiments, the deposition of the dopant-containing layer 122 may be performed by generating a plasma of a deposition species 125. The deposition species 125 may be an ion or radical, and may be directed to the upper surface 105, through the trench 111. The deposition species 125 may be delivered vertically or at a non-zero angle relative to a perpendicular extending from a plane defined by the upper surface 105.

In one embodiment, the dopant-containing layer 122 may be formed by deposition of a surface dopant-containing physisorbed multilayer (e.g., an organo-metallic compound), with or without a precursor, and while the semiconductor substrate 100 is maintained at a temperature between 75-200 ⁰C. The dopant-containing layer 122 may be deposited using ALD, CVD, PECVD, or another wet chemistry or gas-phase-based deposition process. In various non-limiting examples, the surface dopant may be Ga, Al, or B for p-type semiconductor device, or P, Sb, or As for n-type semiconductor device. Meanwhile, the precursors may be organo-metallic compounds, such as allyldiphenylphosphine, Tris (2,4 pentanedionato) gallium(III), phenylboronic acid, or triallylarsine. Alternately, the dopant-containing layer 122 could be formed via wet processing or another surface functionalization method.

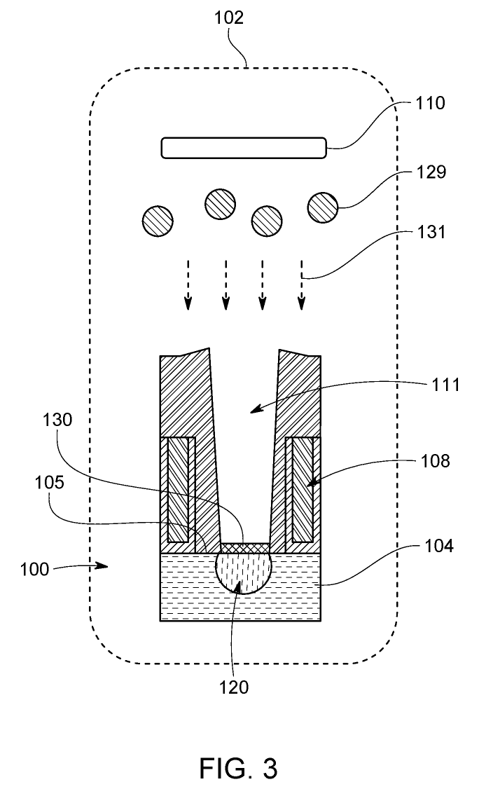

As shown in FIG. 3, another plasma process 131 may be performed to treat the dopant precursor multilayers of dopant layer 122 with radicals 129, e.g. hydrogen radicals, leaving a dopant-containing monolayer 130 within the trench 111. The plasma process 131 may be a plasma clean operation performed using the plasma source 110, as described above. Alternatively, a different plasma source may be used. In some embodiments, the plasma cleaning process is performed with no bias on the wafer.

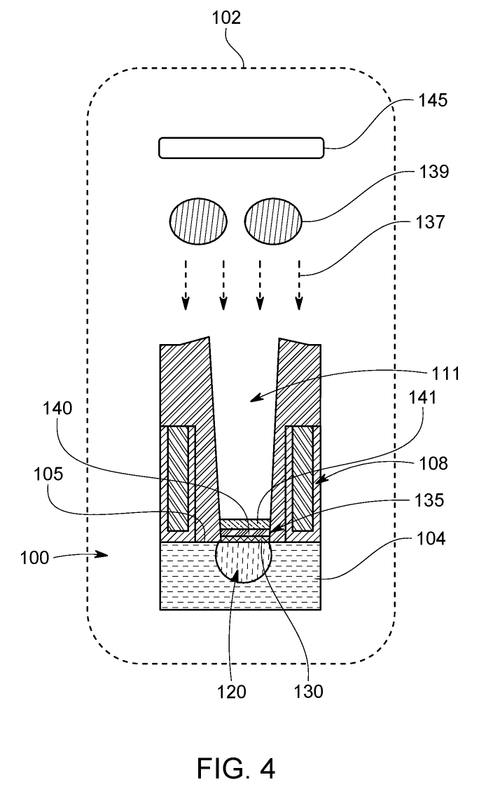

As shown in FIG. 4, a metal deposition process 137 may result in a contact 135 being formed over the dopant-containing monolayer 130 within the trench 111. In some embodiments, the contact 135 may be formed while the semiconductor substrate 100 is maintained at a temperature greater than 250°C. More specifically, a metal (e.g., titanium) may be formed using a metal CVD source 145 at an elevated temperature (e.g., 300-450°C) to incorporate surface dopants during metal silicide formation during interaction with the semiconductor substrate 100, resulting in a metal portion/layer 141 and a metal silicide portion/layer 140 of the contact 135. Maintaining the semiconductor substrate 100 above 300°C is beneficial to break carbon (C) functional groups from the organometallic dopant-containing atom. The organic carbon functionalities on the dopant-containing monolayer 130 will burn off, leaving the dopant atom present to incorporate in the semiconductor lattice at the upper surface 105 of the substrate base 104 during the formation of the metal silicide portion/layer 140 that subsequently forms the contact 135.

In the embodiment shown, the metal deposition process 137 includes depositing Ti 139 for the metal contact formation, resulting in metal silicide portion/layer 140 being titanium silicide (TiSi) and the metal portion/layer 141 being Ti. However, tungsten (W), molybdenum (Mo), and other metal(s) may also be used for contact formation in alternative embodiments. The incorporation of the dopant at this step leads to dopant presence within the surface-most layers of the silicon substrate base 104, which reduces contact resistance.. The TiSi formation of metal silicide portion/layer 140 pulls Si out of the lattice, causing the dopant atoms from dopant-containing organo-metallic monolayer 130 to be incorporated into the crystal lattice spaces vacated by Si atoms. Some of the dopant atoms from the dopant-containing monolayer 130 may also end up in the metal silicide portion/layer 140. However, there is inadequate energy present for the dopant atoms to diffuse deeper than a few atoms or lattice unit cells into the crystalline substrate, so the dopant remains near the interface of the dopant-containing monolayer 130 and the metal silicide portion/layer 140. Advantageously, the doping of the substrate Si lattice causes lowering of the contact resistance by increasing activation of dopants in the lattice near the surface, which bends the bands at the interface. This integrated process flow achieves reduced contact resistance without the problems associated with high-temperature annealing processes, including undesired dopant diffusion deeper into the Si.

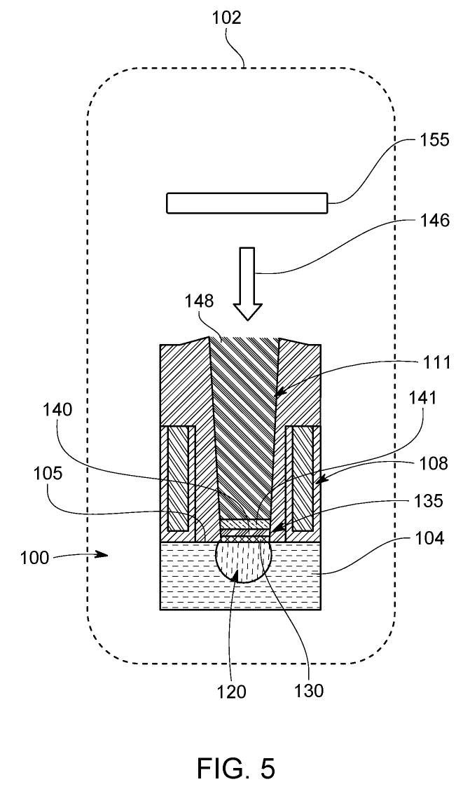

As shown in FIG. 5, processing of the semiconductor substrate 100 may continue, e.g., by performing a deposition process 146 to form a metal fill 148 (e.g., W) within the trench 111, as is known. The metal fill 148 may be formed directly over the contact 135 using, e.g., a metal CVD source 155, which may be the same or different as the metal CVD source 145 depicted in FIG. 4. In various embodiments, the metal fill 148 may constitute a series of deposition steps, which may be a combination of ALD, CVD, PECVD, etc. Formation of the metal fill 148 may include over-filling the trench 111 followed by a CMP or other back etch process.

As shown, the metal fill 148 may be formed atop an exposed upper surface of the first portion/layer 141, wherein the metal fill 148 may be a metal and/or one or more metal-containing compounds. In other embodiments, the metal gap fill 148 may additionally include the formation of a trench liner (not shown), which can be TiN or another material, formed along the exposed sidewalls of the trench 111 and/or atop the first portion/layer 141.

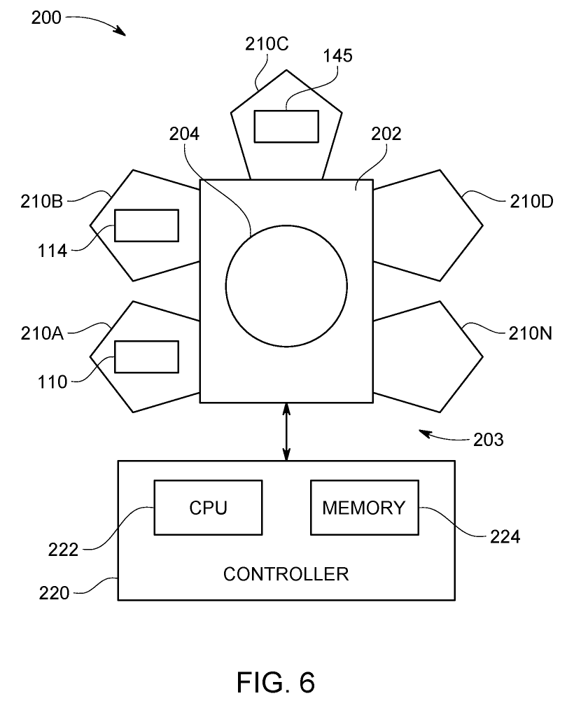

Turning now to FIG. 6, an example semiconductor processing apparatus 200 will be described. In some embodiments, the semiconductor processing apparatus 200 may be a cluster tool operable to perform processes necessary to form the devices described herein. Although non-limiting, the semiconductor processing apparatus 200 may include at least one central transfer station/chamber 202 of a load-lock system 203, and one or more robots 204 within the transfer station/chamber 202, wherein the robot 204 is operable to move a robot blade and a wafer to and from each of a plurality of processing chambers 210A – 210N connected with, or positioned adjacent to, the transfer station/chamber 202, without breaking vacuum. In some embodiments, the processing chambers 210A – 210N may support various ion and/or plasma treatments including ion implantation, material deposition, material etching, plasma processes, and more. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some embodiments, processing chamber 210A may include a first processing tool operable to perform a first plasma treatment on a semiconductor substrate to remove a residue layer along a surface of the semiconductor substrate. The first processing tool may be further operable to perform a radical cleaning process following formation of a dopant-containing layer, such as dopant-containing layer 122. Alternatively, the radical cleaning process may be performed by in a different processing chamber using a same or different processing tool. Following the radical cleaning process, a dopant-containing monolayer may remain, such as dopant-containing monolayer 130. The first processing tool may include the plasma source 110 described herein.

Processing chamber 210B may include a second processing tool operable to form a dopant-containing layer over the surface of the semiconductor substrate. In some embodiments, the dopant-containing layer is formed over a doped contact area present at the surface of the semiconductor substrate. In some embodiments, the second processing tool may include the second source 114 described herein.

Processing chamber 210C may include a third processing tool operable to form a gate contact within the trench by forming one or more metal layers over the dopant-containing layer. In some embodiments, the metal layer(s) are formed while the semiconductor substrate is at a temperature greater than 250°C. In some embodiments, the semiconductor substrate may be at the elevated temperature after being heated on a preheat station and/or a platen of the tool, which heats the semiconductor substrate during processing. In some embodiments, the third processing tool may be the same or similar to the metal CVD source 145 described herein.

Processing chamber 210C may also be used to perform a deposition process to form a metal fill (e.g., W) within the trench. Alternatively, the metal CVD source 155 may be located in another processing chamber, e.g., processing chamber 210D.

As the semiconductor substrate passes between processing chambers 210A – 210D, the semiconductor substrate is maintained under vacuum conditions over a process duration spanning the first plasma treatment, the second treatment, implant processes, the deposition process, and all transfer steps between the chambers performing said processes.

A system controller 220 is in communication with the robot 204, the transfer station/chamber 202, and the plurality of processing chambers 210A – 210N. The system controller 220 can be any suitable component that can control the processing chambers 210A – 210N and robot(s) 204, as well as the processes occurring within the process chambers 210A – 210N. For example, the system controller 220 can be a computer including a central processing unit 222, memory 224, suitable circuits/logic/instructions, and storage.

Processes or instructions may generally be stored in the memory 224 of the system controller 220 as a software routine that, when executed by the processor 222, causes the processing chambers 210A – 210N to perform processes of the present disclosure. The software routine may also be stored and/or executed by a second processor (not shown) that is remotely located from the hardware being controlled by the processor 222. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 222, transforms the general-purpose computer into a specific purpose computer (controller) that controls the chamber operation such that the processes are performed.

In various embodiments, design tools can be provided and configured to create the datasets used to pattern the semiconductor layers of the device, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

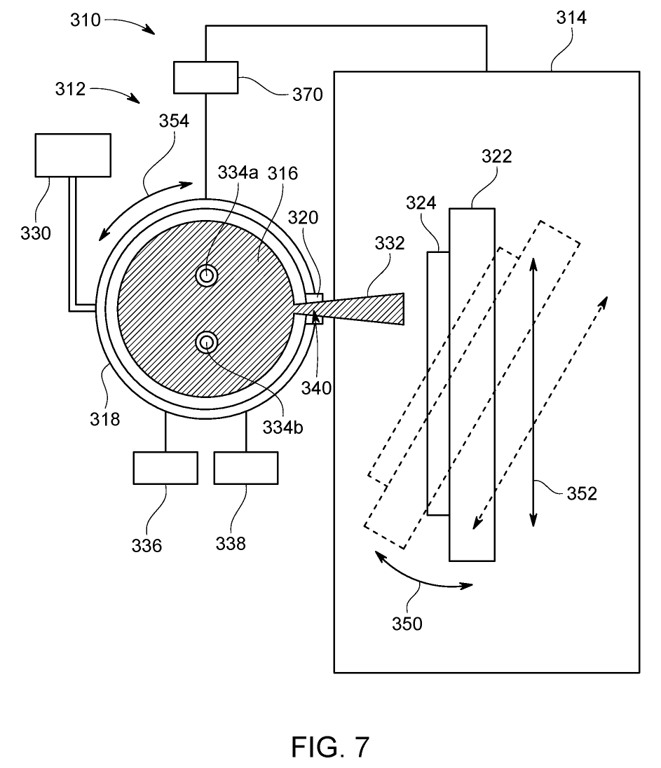

FIG. 7 illustrates a portion of a system 310 useful to perform processes described herein, such as one or more plasma treatments/processes. The system 310 may generally include a plasma source 312 disposed adjacent a process chamber 314. In various embodiments, the system 310 may correspond to the plasma source 110 or to the second source 114, described above. The plasma source 312 may be adapted to generate an energetic plasma 316 in a plasma chamber 318, and to emit the plasma 316, e.g., through a nozzle 320 of the plasma chamber 318, or alternatively with a second plate with a separate aperture situated a specific distance away from 318. While the plasma chamber 318 is depicted as being generally cylindrical in shape, the present disclosure is not limited in this regard, and the plasma chamber 318 may be implemented in a variety of alterative shapes and configurations.

The process chamber 314 may contain a wafer support or platen 322 adapted to support a substrate 324 (e.g., a silicon wafer) in a confronting relationship with the nozzle 320 of the plasma chamber 318. The substrate 324 may be the same or similar to the semiconductor substrate 100 described herein. In various embodiments, the platen 322 may be adapted to forcibly retain the substrate 324, such as via electrostatic clamping or mechanical clamping. Additionally, the platen 322 may include a heating element (not shown) for controllably heating the substrate 324 to a desired temperature (e.g., a temperature in a range between room temperature and 550 degrees Celsius) to enhance deposition processes. Alternatively, or additionally, the platen 322 may include one or more cooling elements (not shown) for controllably cooling the substrate to a desired temperature, e.g., a temperature in a range between approximately -150C and room temperature.

The plasma source 312 of the system 310 may be configured to generate the plasma 316 from a gaseous species supplied to the plasma chamber 318 by one or more gas sources 330. The plasma 316 (and particularly free radicals within the plasma) may be directed at the substrate 324. In some non-limiting embodiments, the plasma 316 is delivered to the substrate 324 as a ribbon beam 332. In various embodiments, the plasma source 312 may be a radio frequency (RF) plasma source (e.g., an inductively coupled plasma (ICP) source, a capacitively coupled plasma (CCP) source, a helicon source, an electron cyclotron resonance (ECR) source, etc.). For example, the plasma source 312 may include electrodes 334a, 334b, an RF generator 336, and an RF matching network 338 for igniting and sustaining the plasma 316 in a manner familiar to those of ordinary skill in the art. The present disclosure is not limited in this regard.

The plasma 316 generated in the plasma chamber 318 may contain ionized gas species (ions), electrons, excited neutrals, and free radicals. When a plasma enhanced chemical vapor deposition (PECVD) system is used, the substrate 324 may be located in the same chamber as the plasma 316, and free radicals within the plasma are distributed over the surface of the substrate 324 in a directionally-nonspecific, isotropic manner to form a thin film of generally uniform thickness on the exposed surface(s) of the substrate. In another embodiment, the plasma chamber 318 of the system 310 is separate from the process chamber 314 where the platen 322 and the substrate 324 reside, and a collimated ribbon beam 332 containing ions, excited neutrals, and/or free radicals of the plasma 316 is extracted from the plasma chamber 318 and is directed at the substrate 324. This is achieved by establishing a pressure differential between the plasma chamber 318 and the process chamber 314, and by collimating the radical beam.

In a non-limiting example, the beam may be extracted through the nozzle 320 or a second aperture plate having an elongated profile. With regard to the pressure differential, the process chamber 314 may be maintained at a first pressure, and the plasma chamber 318 may be maintained at a second pressure higher than the first pressure. In various examples, the first pressure in the process chamber may be in a range of 10⁻⁶ torr to 10⁻² torr, and the second pressure in the plasma chamber 318 may be in a range of 1 millitorr to 1 torr. The present disclosure is not limited in this regard. Thus, the pressure differential between the plasma chamber 318 and the process chamber 314 may provide a motive force for driving free radicals in the plasma 316 from the plasma chamber 318 into the process chamber 314 in the form of the ribbon beam 332.

The platen 322 may be rotatable and movable for pivoting and scanning the substrate 324 relative to the plasma chamber 318 as indicated by arrows 350 and 352. Additionally, or alternatively, the plasma chamber 318 may be rotatable about its long axis as indicated by the arrow 354. Thus, the collimated, free radical-containing ribbon beam 332 may be projected onto the substrate 324 at various angles in a highly directional manner.

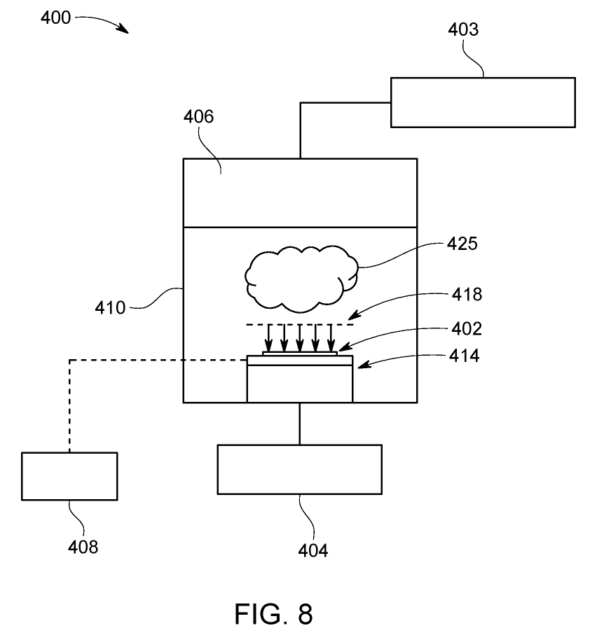

Referring to FIG. 8, an example system 400 (e.g., a PLAD system) operable to provide pulsed RF-excited continuous plasma doping will be described. System 400 may be useful to perform processes described herein, such as one or more plasma treatments/processes on a wafer/substrate 402. More specifically, the system 400 may be used for the plasma clean/treatment steps, i.e, both cleaning of the native oxide off surfaces of the substrate 402 and the post-dopant-containing-layer-deposition clean of the excess physisorbed layers. The system 400 may be used in some embodiments in lieu of the plasma chamber type shown in FIG. 7.

As shown, the system 400 may include a plasma power supply 403, a voltage pulse power supply 404, an RF coil array 406, and a dosimeter 408. Within a plasma chamber 410 is a wafer/substrate 402, which may be the same or similar to the substrate base 104 described above, supported by a platen/pedestal 414. A plasma sheath 418 may be formed above the substrate 402. A temperature of the platen/pedestal 414 may be elevated (e.g., to 500°C or greater) during plasma doping. The dosimeter 408 may be a Faraday dosimeter or other type of sensor that directly measures the dose of ions received by the substrate 402. Although non-limiting, the dosimeter can be located on the pedestal 414, proximate to the substrate 402.

During use, the plasma power supply 403 and the RF coil array 406 deliver radio frequency excitation to generate a plasma 425 when gaseous species are delivered into the plasma chamber 410. For example, the plasma power supply 403 may be an RF powered inductively coupled power source to generate inductively coupled plasma 425, as known in the art. Gaseous species may be delivered from one or more gas sources (not separately shown) to generate ions of any suitable species, such as boron.

The voltage pulse power supply 404 may generate a bias voltage between the substrate 402 and the plasma chamber 410. As such, when the voltage pulse power supply 404 generates a voltage between the plasma chamber 410 and the substrate 402, a similar, but slightly larger, voltage difference is generated between the plasma 425 and the substrate 402. In one non-limiting example, a 5000 V (5 kV) voltage difference established between the plasma chamber 410 and the substrate 402 (or, equivalently, pedestal 414) may generate a voltage difference of approximately 5005 V to 5030 V between the plasma 425 and the substrate 402.

In some embodiments, the voltage pulse power supply 404 may generate a bias voltage as a pulsed voltage signal, wherein the pulsed voltage signal is applied in a repetitive and regular manner, to generate a pulse routine comprising a plurality of extraction voltage pulses. For example, a pulse routine may apply voltage pulses of 500 V magnitude, 1000 V magnitude, 2000 V magnitude, 5000 V magnitude, or 10,000 V magnitude in various non-limiting embodiments. The system 400 may further include a controller (not shown), to control the pulsing routine applied to the substrate 402, in order to provide the PLAD treatment.

According to various embodiments, the plasma 425 may be formed at least in part of ions that constitute a species capable of cleaning and/or treating the substrate 402, as described herein. In various non-limiting embodiments, such suitable species may include a cleaning species, e.g., ions and neutrals, including radicals, or hydrogen (H) or other atomic species. When the plasma 425 is present in the plasma chamber 410, the controller may generate a signal for the voltage pulse power supply 404 to apply a pulse routine to the substrate 402, where the pulse routine constitutes a plurality of extraction voltage pulses. As such, when the extraction voltage pulses are applied between the substrate 402 and plasma 425, ions are extracted in pulsed form from the plasma 425, generating a plurality of ion pulses that are directed to the substrate 402.

In sum, embodiments herein provide surface doping during contact silicidation to reduce resistance thereof. The plasma treatment before deposition of the dopant-containing film results in a hydrogen-terminated surface, which then enables chemisorption of the dopant-containing film onto that surface. Further layers of the dopant-containing film will only be physisorbed, and therefore will be removed by the second treatment step, leaving only a monolayer of the dopant-containing film from which the doping occurs during the contact deposition and silicidation process.

For the sake of convenience and clarity, terms such as "top," "bottom," "upper," "lower," "vertical," "horizontal," "lateral," and "longitudinal" will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word "a" or "an" is to be understood as including plural elements or operations, until such exclusion is explicitly recited. Furthermore, references to "one embodiment" of the present disclosure are not intended as limiting. Additional embodiments may also incorporating the recited features.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
performing a plasma treatment on a semiconductor substrate to remove a residue layer along an exposed surface of the semiconductor substrate;
forming a dopant-containing layer over the exposed surface; and
forming a contact by forming one or more metal layers over the exposed surface.

2. The method of claim 1, wherein the dopant-containing layer is formed by performing a second treatment to the exposed surface.

3. The method of claim 2, further comprising forming a dopant-containing monolayer over the exposed surface by performing a third plasma treatment to the dopant-containing layer.

4. The method of claim 3, wherein the third plasma treatment is a radical cleaning process.

5. The method of claim 2, wherein the plasma treatment is performed by a first processing tool in a first chamber, wherein the second treatment is performed by a second processing tool in a second chamber, wherein the first chamber and the second chamber are part of a same semiconductor cluster tool, and wherein the semiconductor substrate is maintained under vacuum in the semiconductor cluster tool during the plasma treatment and the second treatment, and during all substrate transfer operations between the first chamber and the second chamber.

6. The method of claim 5, wherein the one or more metal layers are formed by a third processing tool in a third chamber.

7. The method of claim 2, wherein the second treatment comprises one of the following deposition processes: atomic layer deposition, chemical vapor deposition, plasma-enhanced chemical vapor deposition, a wet chemistry deposition process, or a gas-phase-based deposition process.

8. The method of claim 1, wherein the plasma treatment comprises a hydrogen radical and a noble gas dilution species maintained at an energy below 100 eV.

9. The method of claim 1, wherein the dopant-containing layer is formed over a contact area of the semiconductor substrate, and wherein the contact area is located along a bottom of a trench defined by a set of gate structures.

10. A method of forming a contact, comprising:
performing a plasma treatment on a semiconductor substrate to remove a residue layer along an upper surface within a trench;
forming a dopant-containing layer over the upper surface; and
forming a contact over the upper surface within the trench by forming one or more metal layers over a dopant-containing monolayer, wherein the dopant-containing monolayer is formed by performing a radical cleaning process to the dopant-containing layer.

11. The method of claim 10, wherein the dopant-containing layer is formed by performing a second treatment to the upper surface, wherein the second treatment comprises one of the following processes: atomic layer deposition, chemical vapor deposition, plasma-enhanced chemical vapor deposition, a wet chemistry deposition, or a gas-phase-base deposition.

12. The method of claim 11, wherein the plasma treatment is performed by a first processing tool in a first chamber, wherein the second treatment is performed by a second processing tool in a second chamber, wherein the first chamber and the second chamber are part of a same semiconductor cluster tool, and wherein the semiconductor substrate is maintained under vacuum in the semiconductor cluster tool during the plasma treatment and the second treatment, and during all substrate transfer operations between the first chamber and the second chamber.

13. The method of claim 12, wherein the one or more metal layers are formed by a third processing tool in a third chamber.

14. The method of claim 10, wherein the plasma treatment comprises a hydrogen radical and a noble gas dilution species maintained at an energy below 100 eV.

15. The method of claim 10, wherein the contact is formed while the semiconductor substrate is at a temperature between 300° C. - 450° C., and wherein the dopant-containing layer is formed while the semiconductor substrate is maintained at a temperature between 75° C. - 200° C.

16. A semiconductor cluster tool, comprising:
a first processing tool in a first chamber, wherein the first processing tool is operable to perform a plasma treatment on a semiconductor substrate to remove a residue layer along an exposed surface of the semiconductor substrate;
a second processing tool in a second chamber, wherein the second processing tool is operable to form a dopant-containing layer over the exposed surface by performing a second treatment to the exposed surface; and
a third processing tool operable to form a metal contact by forming one or more metal layers over a dopant-containing monolayer, wherein the dopant-containing monolayer is formed by performing a radical cleaning process to the dopant-containing layer,
wherein the first chamber and the second chamber are operably connected to a same load-lock system, and wherein the semiconductor substrate is maintained under a continuous vacuum throughout the plasma treatment and the second treatment.

17. The semiconductor cluster tool of claim 16, wherein the second treatment comprises one of the following deposition processes: atomic layer deposition, chemical vapor deposition, plasma-enhanced chemical vapor deposition, a wet chemistry deposition, or a gas-phase-base deposition, and wherein the metal contact is formed using chemical vapor deposition.

18. The semiconductor cluster tool of claim 16, wherein the plasma treatment comprises a hydrogen radical and a noble gas dilution species maintained at an energy below 100 eV.

19. The semiconductor cluster tool of claim 16, wherein the metal contact is formed while the semiconductor substrate is at a temperature between 300°C-450°C.

20. The semiconductor cluster tool of claim 16, wherein the dopant-containing layer is formed over a contact area of the semiconductor substrate, and wherein the contact area is located along a bottom of a trench defined by a set of gate structures.
